(19) United States
(12) Patent Application Publication
(10) Pub. No.: US 2025/0056757 A1
(43) Pub. Date: Feb. 13, 2025

(54) CHASSIS MECHANICAL FEATURE WITH INTEGRATED AIRFLOW HEATER

(71) Applicant: Dell Products L.P., Round Rock, TX (US)

(72) Inventors: Eric TUNKS, Austin, TX (US); Justin BROUGHTON, Pflugerville, TX (US); Julian Y. CHEN, Austin, TX (US); Zach BALOGH, Sugar Land, TX (US); Jacob HERNANDEZ, Colleyville, TX (US); Kristian GERBERDING, Columbus, OH (US); Thomas SATTERWHITE, Houston, TX (US); Kyle SCHLEINSCHOK, Houston, TX (US)

(73) Assignee: Dell Products L.P., Round Rock, TX (US)

(21) Appl. No.: 18/447,668

(22) Filed: Aug. 10, 2023

(51) Int. Cl. H05K 7/20

(52) U.S. Cl. CPC H05K 7/20209; H05K 7/20145

(57) ABSTRACT

An information handling system may include a chassis, an air mover housed within the chassis and configured to drive airflow within the chassis, a heater mechanically coupled to a body of a chassis mechanical feature of the chassis, wherein the heater is located within a path of the airflow driven by the air mover, and a processing device housed within the chassis and configured to implement a thermal control system for controlling the heater to regulate a temperature of the information handling system above a threshold minimum temperature.

### TECHNICAL FIELD

The present disclosure relates in general to information handling systems, and more particularly to a chassis mechanical feature, such as an air shroud, having an integrated airflow heater.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

As processors, graphics cards, random access memory (RAM) and other components in information handling systems have increased in clock speed and power consumption, the amount of heat produced by such components as a side-effect of normal operation has also increased. Often, the temperatures of these components need to be kept within a reasonable range to prevent overheating, instability, malfunction and damage leading to a shortened component lifespan. Accordingly, air movers (e.g., cooling fans and blowers) have often been used in information handling systems to cool information handling systems and their components.

A particular challenge in cooling information handling systems comes in the case of “edge computing,” wherein an information handling system is located, often in a remote environment, in which its surrounding ambient temperature is not climate controlled, as might be the case of a cellular base station. In some instances, ambient temperatures may fluctuate considerably among seasons, meaning cooling requirements of an information handling system may change over time. For example, for hotter ambient temperatures, the information handling system may require significant cooling to maintain electronic components at desirable operating temperatures whereas for colder ambient temperatures, it may be required to heat electronic components of the information handling system to maintain their temperatures above minimum desired temperatures.

### SUMMARY

In accordance with the teachings of the present disclosure, the disadvantages and problems associated with traditional approaches to heating and cooling information handling system components may be substantially reduced or eliminated.

In accordance with embodiments of the present disclosure, an information handling system may include a chassis, an air mover housed within the chassis and configured to drive airflow within the chassis, a heater mechanically coupled to a body of a chassis mechanical feature of the chassis, wherein the heater is located within a path of the airflow driven by the air mover, and a processing device housed within the chassis and configured to implement a thermal control system for controlling the heater to regulate a temperature of the information handling system above a threshold minimum temperature.

In accordance with these and other embodiments of the present disclosure, a chassis mechanical feature may include a body, a heater mechanically coupled to the body, and an electrical connector mechanically coupled to the body, electrically coupled to the heater and configured to electrically couple to a corresponding electrical connector housed in a chassis configured to house the chassis mechanical feature, wherein the electrical connector is configured to deliver electrical energy to the heater.

In accordance with these and other embodiments of the present disclosure, a method ma include mechanically coupling a heater to a body of a chassis mechanical feature, mechanically coupling an electrical connector to the body, and electrically coupling the electrical connector to the heater such that the electrical connector is configured to electrically couple to a corresponding connector housed in a chassis configured to house the chassis mechanical feature, and such that the electrical connector is configured to deliver electrical energy to the heater.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of an example information handling system, in accordance with embodiments of the present disclosure;

FIG. 2A illustrates a perspective view of a top side of an example air shroud, in accordance with embodiments of the present disclosure;

FIG. 2B illustrates a perspective view of a bottom side of an example air shroud, in accordance with embodiments of the present disclosure;

FIG. 3A illustrates a front elevation view of an example air shroud, in accordance with embodiments of the present disclosure;

FIG. 3B illustrates a front elevation view of another example air shroud, in accordance with embodiments of the present disclosure; and

FIG. 4 illustrates a front elevation view of yet another example air shroud, in accordance with embodiments of the present disclosure.

### DETAILED DESCRIPTION

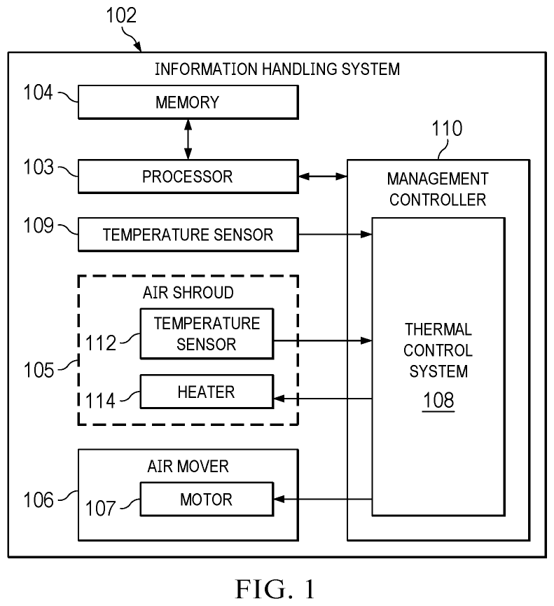

Preferred embodiments and their advantages are best understood by reference to FIGS. 1 through 4, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages, electro-mechanical devices (e.g., air movers), displays, and power supplies.

FIG. 1 illustrates a block diagram of an example information handling system 102, in accordance with embodiments of the present disclosure. In some embodiments, information handling system 102 may comprise a server chassis configured to house one or more servers or “blades.” In other embodiments, information handling system 102 may comprise a personal computer (e.g., a desktop computer, laptop computer, mobile computer, and/or notebook computer). In yet other embodiments, information handling system 102 may comprise a storage enclosure configured to house a plurality of physical disk drives and/or other computer-readable media for storing data. As shown in FIG. 1, information handling system 102 may comprise a processor 103, a memory 104, an air shroud 105 which may include an integrated temperature sensor 112 and heater 114, an air mover 106, a management controller 110 comprising a thermal control system 108, and a temperature sensor 109.

Processor 103 may comprise any system, device, or apparatus operable to interpret and/or execute program instructions and/or process data, and may include, without limitation a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102.

Memory 104 may be communicatively coupled to processor 103 and may comprise any system, device, or apparatus operable to retain program instructions or data for a period of time (e.g., computer-readable media). Memory 104 may comprise random access memory (RAM), electrically erasable programmable read-only memory (EEPROM), a PCMCIA card, flash memory, magnetic storage, opto-magnetic storage, or any suitable selection and/or array of volatile or non-volatile memory that retains data after power to information handling system 102 is turned off.

Air mover 106 may include any mechanical or electro-mechanical system, apparatus, or device operable to move air and/or other gases in order to cool information handling resources of information handling system 102. In some embodiments, air mover 106 may comprise a fan (e.g., a rotating arrangement of vanes or blades which act on the air). In other embodiments, air mover 106 may comprise a blower (e.g., a centrifugal fan that employs rotating impellers to accelerate air received at its intake and change the direction of the airflow). In these and other embodiments, rotating and other moving components of air mover 106 may be driven by a motor 107. The rotational speed of motor 107 may be controlled by an air mover control signal communicated from thermal control system 108 of management controller 110. In these and other embodiments, air mover 106 may be coupled to air shroud 105.

Management controller 110 may comprise any system, device, or apparatus configured to facilitate management and/or control of information handling system 102 and/or one or more of its component information handling resources. Management controller 110 may be configured to issue commands and/or other signals to manage and/or control information handling system 102 and/or its information handling resources. Management controller 110 may comprise a microprocessor, a microcontroller, DSP, ASIC, field programmable gate array (“FPGA”), EEPROM, or any combination thereof. Management controller 110 may also be configured to provide out-of-band management facilities for management of information handling system 102, for example via a management console communicatively coupled to management controller 110. Such management may be made by management controller 110 even if information handling system 102 is powered off or powered to a standby state. In certain embodiments, management controller 110 may include or may be an integral part of a baseboard management controller (BMC), a remote access controller (e.g., a Dell Remote Access Controller or Integrated Dell Remote Access Controller), or an enclosure controller.

As shown in FIG. 1, management controller 110 may include a thermal control system 108. Thermal control system 108 may include any system, device, or apparatus configured to receive one or more signals indicative of one or more temperatures within information handling system 102 (e.g., one or more signals from temperature sensor 109 and/or temperature sensor 112), and based on such signals, calculate an air mover driving signal to maintain an appropriate level of cooling, increase cooling, or decrease cooling, as appropriate, and communicate such air mover driving signal to air mover 106. In these and other embodiments, thermal control system 108 may be configured to receive information from other information handling resources and calculate the air mover driving signal based on such received information in addition to temperature information. For example, thermal control system 108 may receive thermal requirement information of one or more information handling resources. In addition to temperature information collected from sensors within information handling system 102, thermal control system 108 may also calculate the air mover driving signal based on such information received from information handling resources. Management controller 110 comprising thermal control system 108 may determine, based on received signals, a selected operation mode from a plurality of operation modes of air mover 106.

In addition, based on one or more signals indicative of one or more temperatures within information handling system 102 (e.g., one or more signals from temperature sensor 109 and/or temperature sensor 112) and/or other information (e.g., thermal requirement information of one or more information handling resources), thermal control system 108 may control operation of heater 114, including without limitation enabling or disabling (e.g., turning on or off) heater 114 and/or controlling a temperature of heater 114.

Temperature sensor 109 may be any system, device, or apparatus (e.g., a thermometer, thermistor, etc.) configured to communicate a signal indicative of a temperature within information handling system 102 to thermal control system 108 and/or another component of information handling system 102. In some embodiments, information handling system 102 may comprise a plurality of temperature sensors 109, wherein each temperature sensor 109 detects a temperature of a particular component and/or location within information handling system 102.

Air shroud 105 may include any system, device, or apparatus configured to direct airflow to cool information handling system components. Air shroud 105 may be positioned within the airflow path of air mover 106 such that air shroud 105 may direct airflow from air mover 106 to one or more components (e.g., processor 103, memory 104) downstream of the air mover 106 and air shroud 105, thus driving airflow to such one or more components. Accordingly, air shroud 105 may define airflow channels so that air driven by air mover 106 passes proximate to cool or heat information handling system components.

Air shroud 105 may have integrated within heater 114. Heater 114 may include any device, system or apparatus configured to generate thermal energy and transfer such thermal energy to airflow proximate to heater 114. For example, in some embodiments, heater 114 may comprise a heating coil and/or electrically resistive material configured to convert electrical energy into thermal energy. In some embodiments, heater 114 may be mechanically coupled to a surface of air shroud 105 via an adhesive, mechanical compression, and/or other suitable manner.

Air shroud 105 may have integrated within temperature sensor 112. Temperature sensor 112 may be any system, device, or apparatus (e.g., a thermometer, thermistor, etc.) configured to communicate a signal indicative of a temperature within information handling system 102 to thermal control system 108 and/or another component of information handling system 102.

In addition to processor 103, memory 104, air shroud 105, air mover 106, management controller 110, and temperature sensor 109, information handling system 102 may include one or more other information handling resources. In addition, for the sake of clarity and exposition of the present disclosure, FIG. 1 depicts one air mover 106 and one temperature sensor 109. In embodiments of the present disclosure, information handling system 102 may include any number of air movers 106 and any number of temperature sensors 109.

In operation, thermal control system 108 may control operation of heater 114 into order to, if conditions warrant, heat airflow passing through air shroud 105, such that such heated airflow heats components (e.g., processor 103, memory 104) of information handling system 102. For example, thermal control system 108 may determine if a temperature reported by temperature sensor 109 and/or temperature sensor 112 is below a respective threshold minimum temperature, and if the reported temperature is below the respective threshold minimum temperature, thermal control system 108 may enable (e.g., turn on) heater 114 until the reported temperature exceeds the respective threshold minimum temperature. Accordingly, thermal control system 108 may control operation of heater 114 to regulate the reported temperature above the respective threshold minimum temperature.

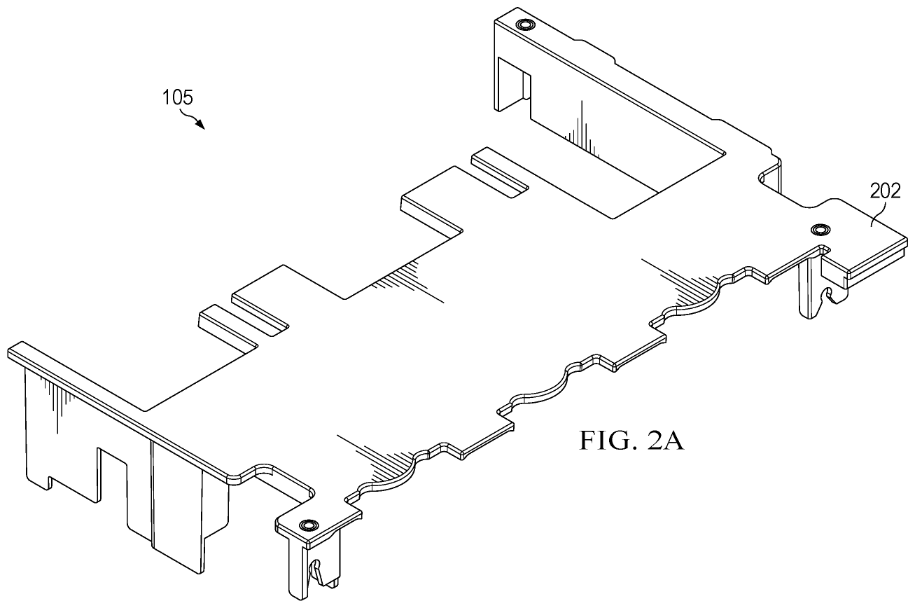

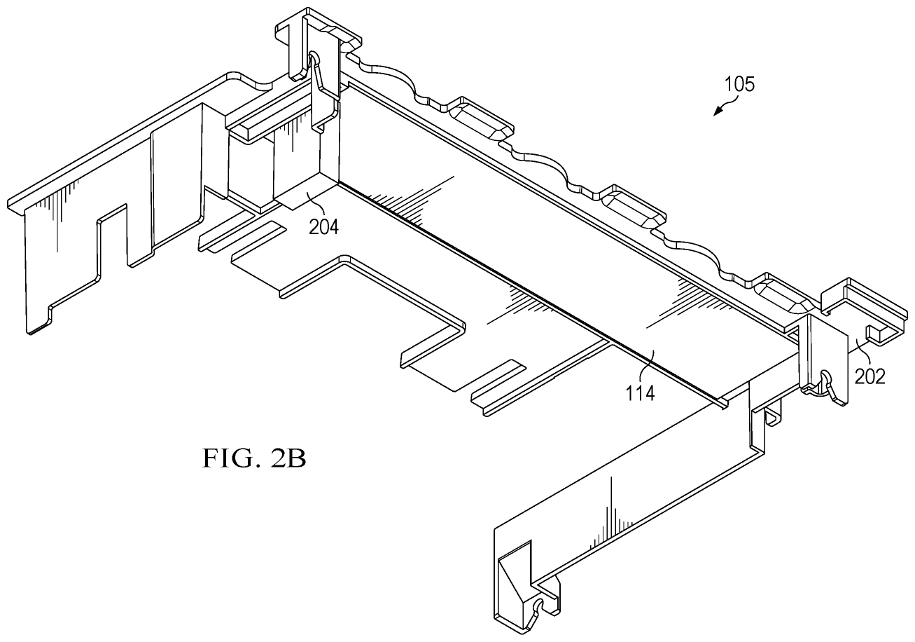

FIG. 2A illustrates a perspective view of a top side of an example air shroud 105, in accordance with embodiments of the present disclosure. FIG. 2B illustrates a perspective view of a bottom side of example air shroud 105, in accordance with embodiments of the present disclosure. As shown in FIGS. 2A and 2B, air shroud 105 may include a shroud body 202 configured (e.g., sized and shaped) to mechanically engage with other components of information handling system 102 (e.g., chassis, motherboard) and form one or more channels to guide airflow through such one or more channels. As also shown in FIG. 2B, heater 114 may be mechanically coupled to a surface of shroud body 202 within at least one of such one or more channels. As further shown in FIG. 2B, a connector 204 may be located within shroud body 202 and may be configured to couple to (e.g., blind mate) with a corresponding connector of a motherboard to which other components (e.g., processor 103, management controller 110) are mounted, thus enabling conduction of electrical energy to heater 114, transmission of control signals to heater 114, and/or transmission of temperature signals from temperature sensor 112 (not explicitly shown in FIGS. 2A and 2B).

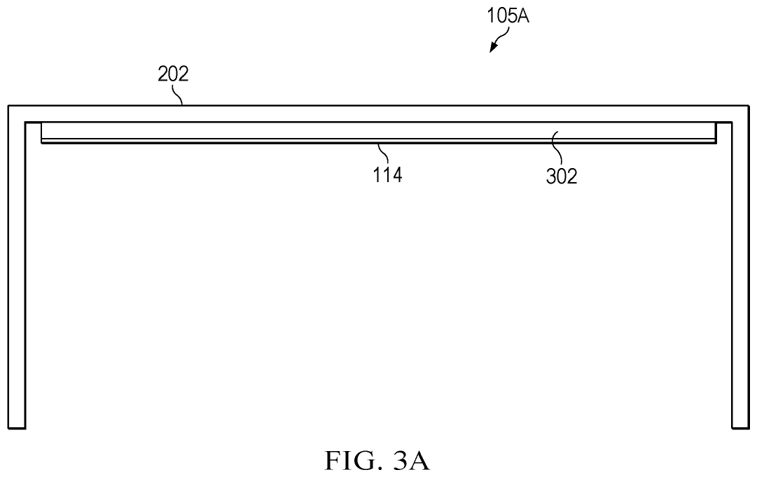

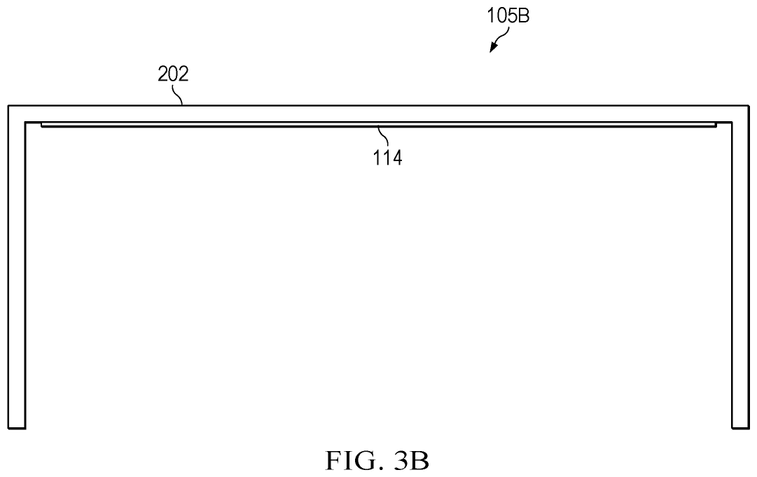

FIG. 3A illustrates a front elevation view of example air shroud 105A, which may be used to implement air shroud 105, in accordance with embodiments of the present disclosure. As shown in FIG. 3A, a layer 302 of heat-insulating material may mechanically interface between shroud body 202 and heater 114. Such an arrangement may be used in circumstances in which it is desirable that heat generated by heater 114 is not transferred to shroud body 202.

FIG. 3B illustrates a front elevation view of another example air shroud 105B, which may be used to implement air shroud 105, in accordance with embodiments of the present disclosure. As shown in FIG. 3B, heater 114 may be mechanically coupled to shroud body 202 without an insulating material interfaced between. Such an arrangement may be used in circumstances in which it is desirable that heat generated by heater 114 is transferred to shroud body 202, or if it is not undesirable that heat generated by heater 114 is transferred to shroud body 202.

Although not shown in the FIGURES, in some embodiments, a thermally conductive pad or other thermally conductive member may be thermally coupled between heater 114 and an information handling resource housed within information handling system 102 to enable heat transfer from heater 114 to such information handling resource.

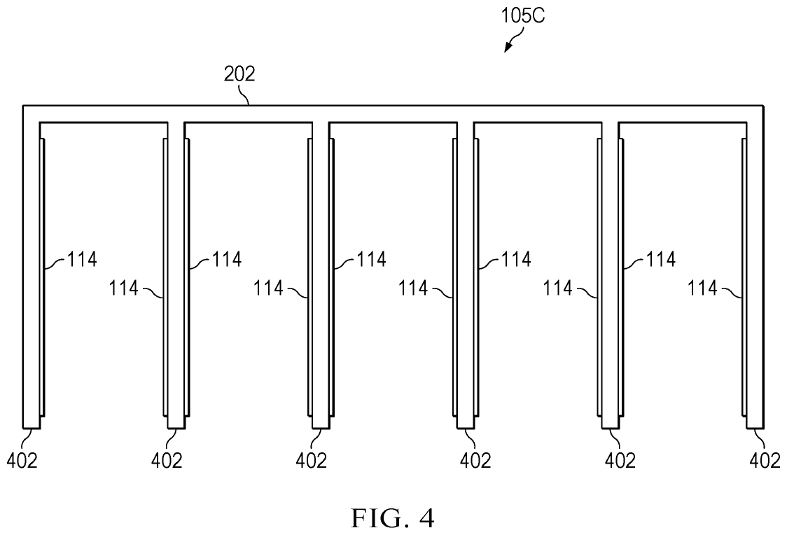

FIG. 4 illustrates a front elevation view of yet another example air shroud 105C, which may be used to implement air shroud 105, in accordance with embodiments of the present disclosure. As shown in FIG. 4, air shroud 105C may have a plurality of walls 402 defining a plurality of airflow channels, and a plurality of heaters 114 may be placed on the surfaces of walls 402, in order to maximize an aggregate surface area of heaters 114 as compared to approaches in which a single airflow channel is present.

Although the foregoing discussion contemplates locating a heater 114 for heating airflow within an air shroud 105 of information handling system 102, it is understood that a heater 114 may also be mechanically coupled to or otherwise integrated within a chassis mechanical feature of information handling system 102 other than an air shroud. For example, in some embodiments, a heater 114 may also be mechanically coupled to or otherwise integrated within a hard disk drive bay, an air mover bay, a wall of a chassis, and/or other suitable chassis mechanical feature.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described above, the principles of the present disclosure may be implemented using any number of techniques, whether currently known or not. The present disclosure should in no way be limited to the exemplary implementations and techniques illustrated in the figures and described above.

Unless otherwise specifically noted, articles depicted in the figures are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. An information handling system comprising:
a chassis;
an air mover housed within the chassis and configured to drive airflow within the chassis;
a heater mechanically coupled to a body of a chassis mechanical feature of the chassis, wherein the heater is located within a path of the airflow driven by the air mover; and
a processing device housed within the chassis and configured to implement a thermal control system for controlling the heater to regulate a temperature of the information handling system above a threshold minimum temperature.

2. The information handling system of claim 1, wherein the chassis mechanical feature comprises an air shroud for guiding airflow driven by the air mover.

3. The information handling system of claim 2, the air shroud comprising a plurality of walls defining a plurality of channels for airflow, and the information handling system further comprising a plurality of heaters including the heater, wherein the plurality of heaters are mechanically coupled to the plurality of walls and communicatively coupled to the processing device.

4. The information handling system of claim 1, the chassis mechanical feature comprising an electrical connector configured to electrically couple to a corresponding electrical connector housed in the chassis, wherein the electrical connector is configured to deliver electrical energy to the heater.

5. The information handling system of claim 4, the electrical connector further configured to convey control signals from the processing device to the heater for controlling operation of the heater.

6. The information handling system of claim 1, the chassis mechanical feature comprising a temperature sensor communicatively coupled to the processing device.

7. The information handling system of claim 1, further comprising a heat insulating material interfaced between the body and the heater.

8. A chassis mechanical feature comprising:
a body;
a heater mechanically coupled to the body; and
an electrical connector mechanically coupled to the body, electrically coupled to the heater and configured to electrically couple to a corresponding electrical connector housed in a chassis configured to house the chassis mechanical feature, wherein the electrical connector is configured to deliver electrical energy to the heater.

9. The chassis mechanical feature of claim 8, wherein the chassis mechanical feature comprises an air shroud for guiding airflow driven by an air mover.

10. The chassis mechanical feature of claim 9, the body comprising a plurality of walls defining a plurality of channels for airflow, and the chassis mechanical feature further comprising a plurality of heaters including the heater, wherein the plurality of heaters are mechanically coupled to the plurality of walls and electrically coupled to the electrical connector.

11. The chassis mechanical feature of claim 8, the electrical connector further configured to convey control signals from a processing device to the heater for controlling operation of the heater.

12. The chassis mechanical feature of claim 8, the chassis mechanical feature comprising a temperature sensor communicatively coupled to the electrical connector.

13. The chassis mechanical feature of claim 8, further comprising a heat insulating material interfaced between the body and the heater.

14. A method comprising:
mechanically coupling a heater to a body of a chassis mechanical feature;
mechanically coupling an electrical connector to the body; and
electrically coupling the electrical connector to the heater such that the electrical connector is configured to electrically couple to a corresponding connector housed in a chassis configured to house the chassis mechanical feature, and such that the electrical connector is configured to deliver electrical energy to the heater.

15. The method of claim 14, wherein the chassis mechanical feature comprises an air shroud for guiding airflow driven by an air mover.

16. The method of claim 15, the body comprising a plurality of walls defining a plurality of channels for airflow, wherein the method further comprises mechanically coupling a plurality of heaters including the heater to the plurality of walls, and electrically coupling the plurality of heaters to the electrical connector.

17. The method of claim 14, further comprising electrically coupling the electrical connector to the heater such that the electrical connector is further configured to convey control signals from a processing device to the heater for controlling operation of the heater.

18. The method of claim 14, further comprising:
mechanically coupling a temperature sensor to the body; and
communicatively coupling the temperature sensor to the electrical connector.

19. The method of claim 14, further comprising interfacing a heat insulating material between the body and the heater.
